(19) United States
(12) Patent Application Publication
(10) Pub. No.: US 2026/0113968 A1
(43) Pub. Date: Apr. 23, 2026

(54) NITRIDE SEMICONDUCTOR TRANSISTOR

(71) Applicant: SUMITOMO ELECTRIC INDUSTRIES, LTD., Osaka (JP)

(72) Inventor: Yuki IMAZEKI, Osaka (JP)

(21) Appl. No.: 19/353,873

(22) Filed: Oct. 9, 2025

(30) Foreign Application Priority Data
Oct. 18, 2024 (JP) 2024-182946

(51) Int. Cl. H10D 30/47; H10D 30/01; H10D 62/824; H10D 64/64

(52) U.S. Cl. CPC H10D 30/474; H10D 30/475; H10D 62/824; H10D 64/64; H10D 30/015

(57) ABSTRACT

A nitride semiconductor transistor includes a barrier layer including a first top surface having nitrogen polarity; a channel layer located over the first top surface and including a second top surface having the nitrogen polarity, the channel layer having a first polarization in a first direction; and a ferroelectric layer located over the second top surface and having a second polarization in a second direction opposite to the first direction.

### CROSS-REFERENCE TO RELATED APPLICATIONS

This application is based on and claims priority to Japanese Patent Application No. 2024-182946, filed on Oct. 18, 2024, the entire contents of which are incorporated herein by reference.

### TECHNICAL FIELD

The present disclosure relates to a nitride semiconductor transistor.

### BACKGROUND

High electron mobility transistors (HEMTs) having a plurality of channels have been proposed. See, for example, Japanese Patent Application Publication No. 2008-252034.

### SUMMARY

A nitride semiconductor transistor of the present disclosure includes: a barrier layer including a first top surface having nitrogen polarity; a channel layer located over the first top surface and including a second top surface having the nitrogen polarity, the channel layer having a first polarization in a first direction; and a ferroelectric layer located over the second top surface and having a second polarization in a second direction opposite to the first direction.

### BRIEF DESCRIPTION OF THE DRAWINGS

FIG. 1 is a cross-sectional diagram illustrating a nitride semiconductor transistor according to an embodiment of the present disclosure.

FIG. 2 is a graph illustrating an example of a band structure of the nitride semiconductor transistor according to the embodiment.

FIG. 3 is a graph illustrating characteristics of nitride semiconductor transistors.

FIG. 4 is a cross-sectional diagram illustrating a production method of the nitride semiconductor transistor according to the embodiment (part 1).

FIG. 5 is a cross-sectional diagram illustrating the production method of the nitride semiconductor transistor according to the embodiment (part 2).

FIG. 6 is a cross-sectional diagram illustrating the production method of the nitride semiconductor transistor according to the embodiment (part 3).

FIG. 7 is a cross-sectional diagram illustrating the production method of the nitride semiconductor transistor according to the embodiment (part 4).

FIG. 8 is a cross-sectional diagram illustrating the production method of the nitride semiconductor transistor according to the embodiment (part 5).

### DETAILED DESCRIPTION

In recent years, there has been a growing need for further improvement in distortion characteristics. As used herein, the distortion characteristics are distortion characteristics of an output amplitude relative to an input amplitude when using a transistor as an amplifier, i.e., amplitude modulation-amplitude modulation characteristics, known as AM-AM characteristics. The AM-AM characteristics are improved as the flatness of mutual conductance is higher.

The present disclosure provides a nitride semiconductor transistor having enhanced distortion characteristics.

### DESCRIPTION OF EMBODIMENTS OF THE PRESENT DISCLOSURE

First, embodiments of the present disclosure will be described.

[1] A nitride semiconductor transistor according to an aspect of the present disclosure includes: a barrier layer including a first top surface having nitrogen polarity; a channel layer located over the first top surface and including a second top surface having the nitrogen polarity, the channel layer having a first polarization in a first direction; and a ferroelectric layer located over the second top surface and having a second polarization in a second direction opposite to the first direction.

The first top surface of the barrier layer has nitrogen polarity, the second top surface of the channel layer has nitrogen polarity, the channel layer has the first polarization, and the ferroelectric layer has the second polarization directed in the second direction opposite to the first direction. With this configuration, the channel layer can include a two-dimensional electron gas near the bottom surface of the channel layer and near the second top surface of the channel layer. This can enhance flatness of mutual conductance, thereby enhancing distortion characteristics (AM-AM characteristics) of the output amplitude relative to the input amplitude.

[2] In [1], the channel layer may include a bottom surface opposite to the second top surface, and the channel layer may include a first two-dimensional electron gas positioned closer to the bottom surface than to the second top surface and a second two-dimensional electron gas positioned closer to the second top surface than to the bottom surface. In this case, mainly, the first two-dimensional electron gas is generated through spontaneous polarization of the barrier layer, and the second two-dimensional electron gas is generated through spontaneous polarization of the ferroelectric layer.

[3] In [1] or [2], the ferroelectric layer may be a nitride layer containing aluminum, and at least one selected from the group consisting of scandium, boron, and yttrium. In this case, the ferroelectric layer tends to have a large remnant polarization.

[4] In [3], the ferroelectric layer may be an aluminum scandium nitride layer, and in the aluminum scandium nitride layer, a ratio of a number of scandium atoms to a total number of aluminum atoms and the scandium atoms may be 40% or less. In this case, the aluminum scandium nitride layer tends to have a wurtzite-type crystal structure.

[5] In [3], the ferroelectric layer may be an aluminum yttrium nitride layer, and in the aluminum yttrium nitride layer, a ratio of a number of yttrium atoms to a total number of aluminum atoms and the yttrium atoms may be 80% or less. In this case, the aluminum yttrium nitride layer tends to have a wurtzite-type crystal structure.

[6] In [1] or [2], the ferroelectric layer may be a hafnium oxide layer containing at least one selected from the group consisting of zirconium, yttrium, lanthanum, and silicon. In this case, the ferroelectric layer tends to have a large remnant polarization.

[7] In [6], the ferroelectric layer may be a hafnium zirconium oxide layer, and in the hafnium zirconium oxide layer, a ratio of a number of zirconium atoms to a total number of hafnium atoms and the zirconium atoms may be 45% or more and 55% or less. In this case, a two-dimensional electron gas having a high concentration is readily obtained.

[8] In [6], the ferroelectric layer may be a hafnium yttrium oxide layer, and in the hafnium yttrium oxide layer, a ratio of a number of yttrium atoms to a total number of hafnium atoms and the yttrium atoms may be 3% or more and 7% or less. In this case, a two-dimensional electron gas having a high concentration is readily obtained.

[9] In [6], the ferroelectric layer may be a hafnium lanthanum oxide layer, and in the hafnium lanthanum oxide layer, a ratio of a number of lanthanum atoms to a total number of hafnium atoms and the lanthanum atoms may be 1% or more and 7% or less. In this case, a two-dimensional electron gas having a high concentration is readily obtained.

[10] In [6], the ferroelectric layer may be a hafnium silicon oxide layer, and in the hafnium silicon oxide layer, a ratio of a number of silicon atoms to a total number of hafnium atoms and the silicon atoms may be 2% or more and 9% or less. In this case, a two-dimensional electron gas having a high concentration is readily obtained.

[11] In [1] or [2], the ferroelectric layer may be an oxide layer containing at least one selected from the group consisting of barium, bismuth, lead, and titanium, and having a perovskite-type crystal structure. In this case, the ferroelectric layer tends to have a large remnant polarization.

### Details of Embodiments of Present Disclosure

Embodiments of the present disclosure will be described below in detail, but the present disclosure is not limited thereto. In the present specification and drawings, components having substantially the same functional configuration are denoted by the same symbols, and duplicate description thereof may be omitted. In the present disclosure, the “plan view” means viewing an object from above. In the present disclosure, a direction in which the nitride semiconductor layer is located as viewed from the substrate is defined as being above.

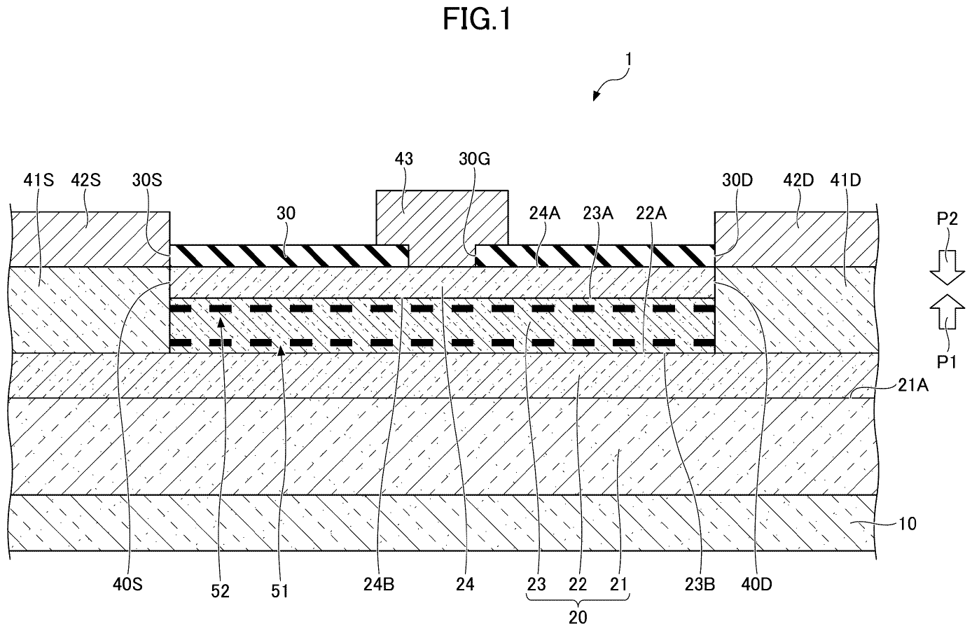

An embodiment of the present disclosure relates to a nitride semiconductor transistor. The nitride semiconductor transistor is, for example, a gallium nitride-based high electron mobility transistor (HEMT). FIG. 1 is a cross-sectional diagram illustrating the nitride semiconductor transistor according to the embodiment.

As illustrated in FIG. 1, a nitride semiconductor transistor 1 according to the embodiment includes a substrate 10, a nitride semiconductor layer 20, a ferroelectric layer 24, an insulating film 30, a regrowth layer 41S, a regrowth layer 41D, a gate electrode 43, a source electrode 42S, and a drain electrode 42D.

The substrate 10 is, for example, a semi-insulating silicon carbide (SiC) substrate. When the substrate 10 is an SiC substrate, the top surface of the substrate 10 is a carbon (C) polar surface.

The nitride semiconductor layer 20 includes a buffer layer 21, a barrier layer 22, and a channel layer 23. The nitride semiconductor layer 20 may include a nucleation layer between the substrate 10 and the buffer layer 21.

The buffer layer 21 is located over the substrate 10. The buffer layer 21 includes a top surface 21A having nitrogen polarity. The buffer layer 21 is, for example, a gallium nitride (GaN) layer. The thickness of the buffer layer 21 is, for example, 100 nanometers (nm) or more and 2,000 nanometers (nm) or less.

The barrier layer 22 is located over the top surface 21A of the buffer layer 21. The barrier layer 22 includes a top surface 22A having nitrogen polarity. The barrier layer 22 is, for example, an aluminum gallium nitride (AlGaN) layer. The electron affinity of the barrier layer 22 is lower than the electron affinity of the channel layer 23. The band gap of the barrier layer 22 is greater than the band gap of the channel layer 23. The thickness of the barrier layer 22 is, for example, 5 nm or more and 40 nm or less. The composition of the barrier layer 22 is, for example, Al_{Z}Ga_{1-Z}N (0.15≤Z≤0.55). That is, in the AlGaN layer, a ratio of the number of Al atoms to the total number of the Al atoms and Ga atoms (Al compositional ratio) is 15% or more and 55% or less. The conductivity type of the barrier layer 22 is, for example, an n-type or undoped type (i-type). The top surface 22A is an example of the first top surface.

The channel layer 23 is located over the top surface 22A of the barrier layer 22. The channel layer 23 includes a top surface 23A having nitrogen polarity, and a bottom surface 23B opposite to the top surface 23A. The channel layer 23 has a polarization P1 directed from the bottom surface 23B toward the top surface 23A. The channel layer 23 is, for example, a gallium nitride (GaN) layer. The thickness of the channel layer 23 is, for example, 5 nm or more and 40 nm or less. The conductivity type of the channel layer 23 is, for example, an n-type or undoped type (i-type). The top surface 23A is an example of the second top surface, and the polarization P1 is an example of the first polarization.

The ferroelectric layer 24 is located over the top surface 23A of the channel layer 23. The ferroelectric layer 24 includes a top surface 24A, and a bottom surface 24B opposite to the top surface 24A. The ferroelectric layer 24 has a polarization P2 directed from the top surface 24A toward the bottom surface 24B. That is, the polarization P2 is directed opposite to the polarization P1. The polarization P2 is an example of the second polarization.

A recess 40S for a source and a recess 40D for a drain are formed in a stack of the ferroelectric layer 24 and the nitride semiconductor layer 20. The recess 40S and the recess 40D penetrate through the ferroelectric layer 24 and the channel layer 23. The recess 40S and the recess 40D may further penetrate through the barrier layer 22. The bottom of the recess 40S and the bottom of the recess 40D may be located in the barrier layer 22 or may be located in the buffer layer 21.

The insulating film 30 is located over the top surface 24A of the ferroelectric layer 24. The insulating film 30 is, for example, a silicon nitride (SiN) film. The thickness of the insulating film 30 is, for example, 5 nm or more and 100 nm or less. An opening 30S for a source, an opening 30D for a drain, and an opening 30G for a gate are formed in the insulating film 30. The opening 30S is continuous with the recess 40S, and the opening 30D is continuous with the recess 40D. In the plan view, the opening 30G is located between the opening 30S and the opening 30D. The opening 30G reaches the ferroelectric layer 24.

The regrowth layer 41S is located over the barrier layer 22 or the buffer layer 21 in the recess 40S. The regrowth layer 41D is located over the barrier layer 22 or the buffer layer 21 in the recess 40D. The regrowth layer 41S and the regrowth layer 41D are, for example, an n-type GaN layer. The regrowth layer 41S and the regrowth layer 41D contain germanium (Ge) or silicon (Si) as n-type impurities.

The source electrode 42S is located over the regrowth layer 41S, and the drain electrode 42D is located over the regrowth layer 41D. The source electrode 42S contacts the regrowth layer 41S, and the drain electrode 42D contacts the regrowth layer 41D. The source electrode 42S is in ohmic contact with the regrowth layer 41S, and the drain electrode 42D is in ohmic contact with the regrowth layer 41D.

In the plan view, the gate electrode 43 is located between the source electrode 42S and the drain electrode 42D. The gate electrode 43 is located over the insulating film 30, and contacts the ferroelectric layer 24 through the opening 30G.

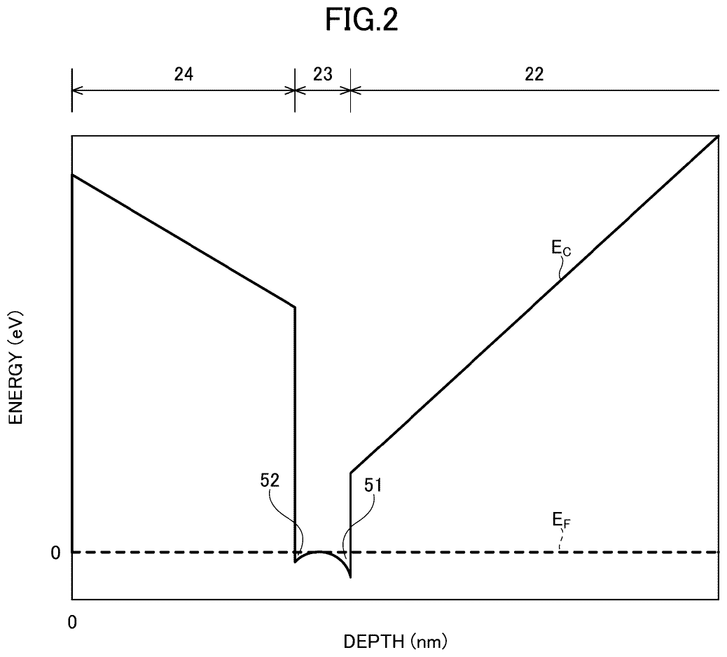

Here, an example of a band structure of the nitride semiconductor transistor 1 will be described. FIG. 2 is a graph illustrating an example of the band structure of the nitride semiconductor transistor 1 according to the embodiment. FIG. 2 illustrates a Fermi level E_{F} and a lower end E_{C} of a conduction band. In FIG. 2, the horizontal axis indicates a depth from the top surface 24A of the ferroelectric layer 24, and the vertical axis indicates energy based on the Fermi level E_{F}.

In the nitride semiconductor transistor 1, the top surface 22A of the barrier layer 22 has nitrogen polarity, and the top surface 23A of the channel layer 23 has nitrogen polarity. Also, the channel layer 23 has the polarization P1, and the ferroelectric layer 24 has the polarization P2 directed opposite to the polarization P1. Therefore, as illustrated in FIGS. 1 and 2, a two-dimensional electron gas (2DEG) 51 is generated near the bottom surface 23B of the channel layer 23, and a two-dimensional electron gas 52 is generated near the top surface 23A of the channel layer 23. That is, the channel layer 23 includes the two-dimensional electron gas 51 positioned closer to the bottom surface 23B than to the top surface 23A, and the two-dimensional electron gas 52 positioned closer to the top surface 23A than to the bottom surface 23B. Mainly, the two-dimensional electron gas 51 is generated through spontaneous polarization of the barrier layer 22, and the two-dimensional electron gas 52 is generated through spontaneous polarization of the ferroelectric layer 24. The two-dimensional electron gas 51 is an example of the first two-dimensional electron gas, and the two-dimensional electron gas 52 is an example of the second two-dimensional electron gas.

Because the channel layer 23 includes the two-dimensional electron gas 51 and the two-dimensional electron gas 52, the flatness of mutual conductance gm can be improved, and the distortion characteristics (AM-AM characteristics) of the output amplitude relative to the input amplitude can be enhanced. That is, it is possible to improve linearity of a source-drain current Ids relative to a gate-source voltage Vgs.

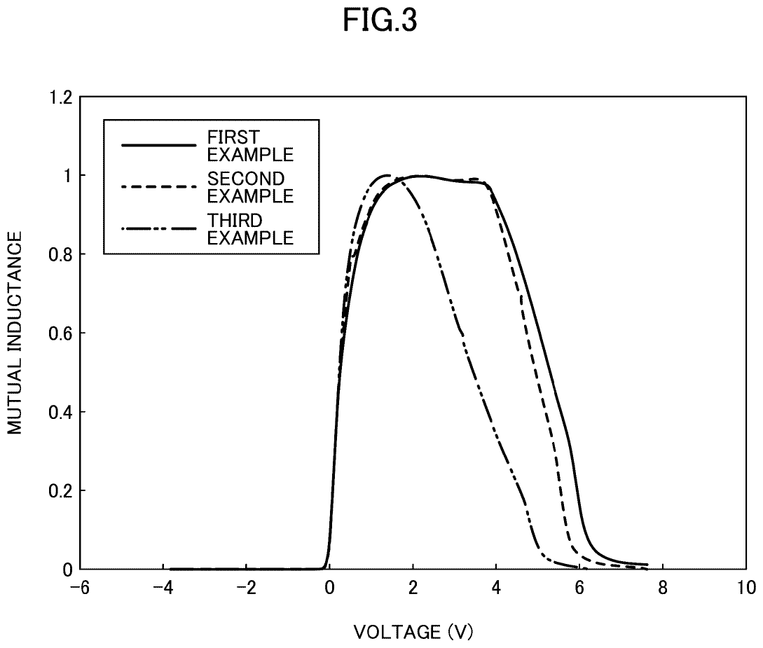

FIG. 3 is a graph illustrating characteristics of three different nitride semiconductor transistors. A first example represents the embodiment. A second example is an example in which indium nitride (InN) is contained in a back barrier layer as in a compound semiconductor device described in Japanese Patent Application Publication No. 2008-252034. A third example is an example identical to the embodiment except that the ferroelectric layer 24 is removed, and only one two-dimensional electron gas is generated. In FIG. 3, a voltage on the horizontal axis indicates a difference (Vgs-Vth) between the gate-source voltage Vgs and a threshold voltage Vth, and the vertical axis indicates a mutual conductance normalized by a peak value.

As illustrated in FIG. 3, the flatness of mutual conductance is higher in the first and second examples than in the third example. This is because two two-dimensional electron gases can be contained in the first and second examples. The flatness of mutual conductance of the first example is higher than that of the second example. This is because, in the second example, indium contained in indium nitride is diffused into the channel layer in the formation of the channel layer, causing a reduction in mobility of electrons, while such diffusion does not occur in the first example.

The ferroelectric layer 24 is, for example, a nitride layer having a wurtzite-type crystal structure, a hafnium oxide layer, or an oxide layer having a perovskite-type crystal structure.

The nitride layer is, for example, a nitride layer containing aluminum (Al), and at least one selected from the group consisting of scandium (Sc), boron (B), and yttrium (Y). In this case, the ferroelectric layer 24 tends to have a large remnant polarization. When the ferroelectric layer 24 is an aluminum scandium nitride layer, and in the aluminum scandium nitride layer, a ratio of the number of Sc atoms to the total number of Al and the Sc atoms (Sc compositional ratio) is 40% or less, the aluminum scandium nitride layer tends to have a wurtzite-type crystal structure. When the ferroelectric layer 24 is an aluminum yttrium nitride layer, and in the aluminum yttrium nitride layer, a ratio of the number of Y atoms to the total number of Al atoms and the Y atoms (Y compositional ratio) is 80% or less, the aluminum yttrium nitride layer tends to have a wurtzite-type crystal structure. The ferroelectric layer 24 may further contain gallium (Ga), indium (In), or both. When the ferroelectric layer 24 contains gallium, it is possible to lower a coercive electric field of the ferroelectric layer 24.

The hafnium oxide layer is, for example, a hafnium oxide layer containing at least one selected from the group consisting of zirconium (Zr), yttrium (Y), lanthanum (La), and silicon (Si). In this case, the ferroelectric layer 24 tends to have a large remnant polarization. When the ferroelectric layer 24 is a hafnium zirconium oxide layer, and in the hafnium zirconium oxide layer, a ratio of the number of Zr atoms to the total number of Hf atoms and the Zr atoms (Zr compositional ratio) is 45% or more and 55% or less, the two-dimensional electron gases 51 and 52 having a high concentration, e.g., 1×10¹¹ cm⁻² or more and 1×10¹⁴ cm⁻2 or less, are readily obtained. When the ferroelectric layer 24 is a hafnium yttrium oxide layer, and in the hafnium yttrium oxide layer, a ratio of the number of Y atoms to the total number of Hf atoms and the Y atoms (Y compositional ratio) is 3% or more and 7% or less, the two-dimensional electron gases 51 and 52 having a high concentration are readily obtained. When the ferroelectric layer 24 is a hafnium lanthanum oxide layer, and in the hafnium lanthanum oxide layer, a ratio of the number of La atoms to the total number of Hf atoms and the La atoms (La compositional ratio) is 1% or more and 7% or less, the two-dimensional electron gases 51 and 52 having a high concentration are readily obtained. When the ferroelectric layer 24 is a hafnium silicon oxide layer, and in the hafnium silicon oxide layer, a ratio of the number of Si atoms to the total number of Hf atoms and the Si atoms (Si compositional ratio) is 2% or more and 9% or less, the two-dimensional electron gases 51 and 52 having a high concentration are readily obtained.

The Sc compositional ratio, Y compositional ratio, Zr compositional ratio, La compositional ratio, and Si compositional ratio can be measured, for example, through transmission electron microscope-energy dispersive X-ray spectroscopy (TEM-EDX), secondary ion mass spectrometry (SIMS), or X-ray photoelectron spectroscopy.

The oxide layer having a perovskite-type crystal structure is, for example, an oxide layer containing at least one selected from the group consisting of barium (Ba), bismuth (Bi), lead (Pb), and titanium (Ti). In this case, the ferroelectric layer 24 tends to have a large remnant polarization.

The ferroelectric layer 24 may further contain at least one selected from the group consisting of indium (In), selenium (Se), molybdenum (Mo), and tellurium (Te).

The direction of the polarization of the ferroelectric layer 24 can be identified by measuring an electric field inside the ferroelectric layer 24 using a transmission electron microscope (TEM) or the like.

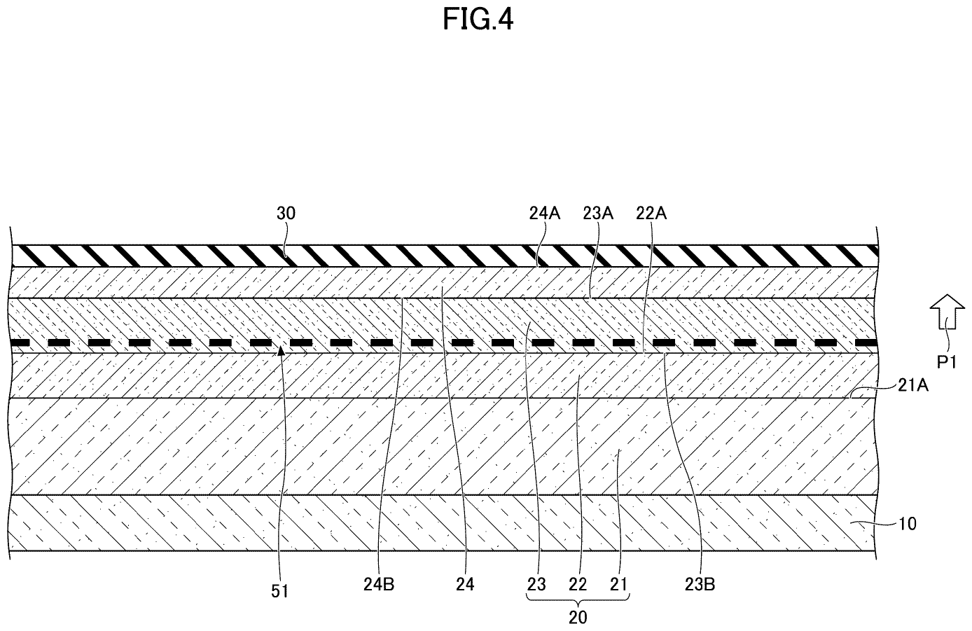

Next, a production method of the nitride semiconductor transistor 1 according to the embodiment will be described. FIGS. 4 to 8 are cross-sectional diagrams illustrating the production method of the nitride semiconductor transistor 1 according to the embodiment.

First, as illustrated in FIG. 4, the buffer layer 21, the barrier layer 22, and the channel layer 23 are sequentially formed over the substrate 10, for example, through metal organic chemical vapor deposition (MOCVD). At this time, the top surface 21A of the buffer layer 21, the top surface 22A of the barrier layer 22, and the top surface 23A of the channel layer 23 have nitrogen polarity, and the two-dimensional electron gas 51 is generated near the bottom surface 23B of the channel layer 23. The channel layer 23 has the polarization P1 directed from the bottom surface 23B toward the top surface 23A.

Next, the ferroelectric layer 24 is formed over the channel layer 23, and the insulating film 30 is formed over the ferroelectric layer 24. The ferroelectric layer 24 can be formed, for example, through sputtering, chemical vapor deposition (CVD), electron beam epitaxy (MBE), or atomic layer deposition (ALD). At this time, the polarization of the ferroelectric layer 24 may be directed in any direction.

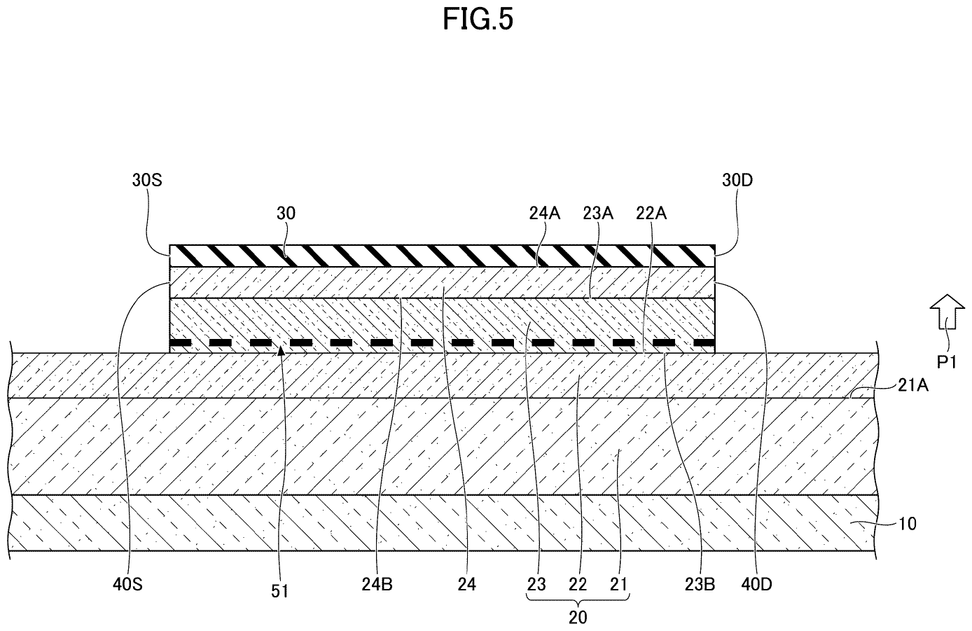

Next, as illustrated in FIG. 5, the opening 30S for the source and the opening 30D for the drain are formed in the insulating film 30, and the recess 40S for the source and the recess 40D for the drain are formed in the nitride semiconductor layer 20. The opening 30S, the opening 30D, the recess 40S, and the recess 40D can be formed, for example, through reactive ion etching (RIE) or ion milling using a mask (not shown).

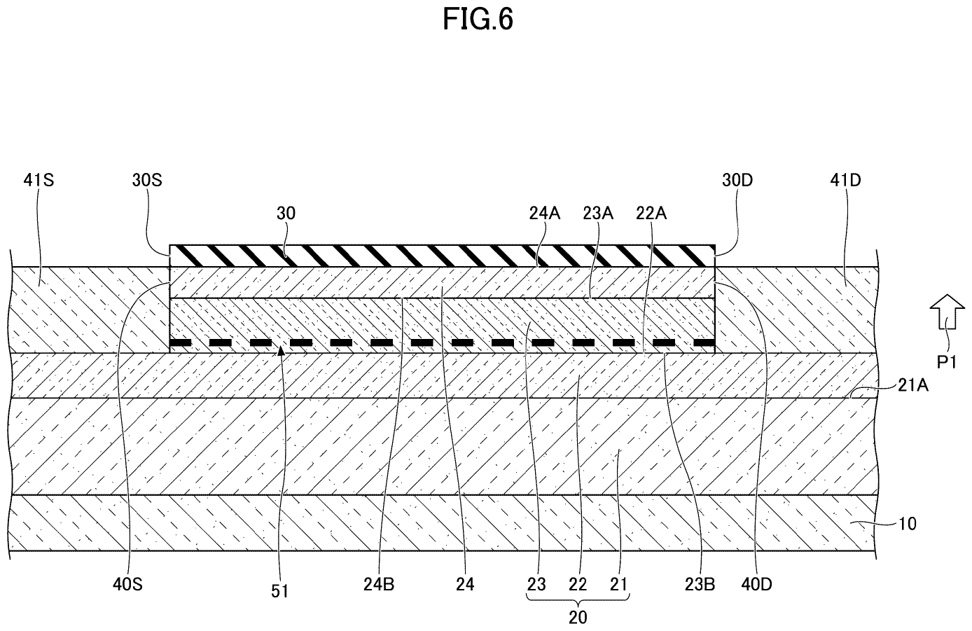

Next, as illustrated in FIG. 6, the regrowth layer 41S is formed over the barrier layer 22 or the buffer layer 21 in the recess 40S, and the regrowth layer 41D is formed over the barrier layer 22 or the buffer layer 21 in the recess 40D. The regrowth layer 41S and the regrowth layer 41D can be formed, for example, through physical vapor deposition (PVD) (e.g., vapor deposition, sputtering, or MBE) or MOCVD.

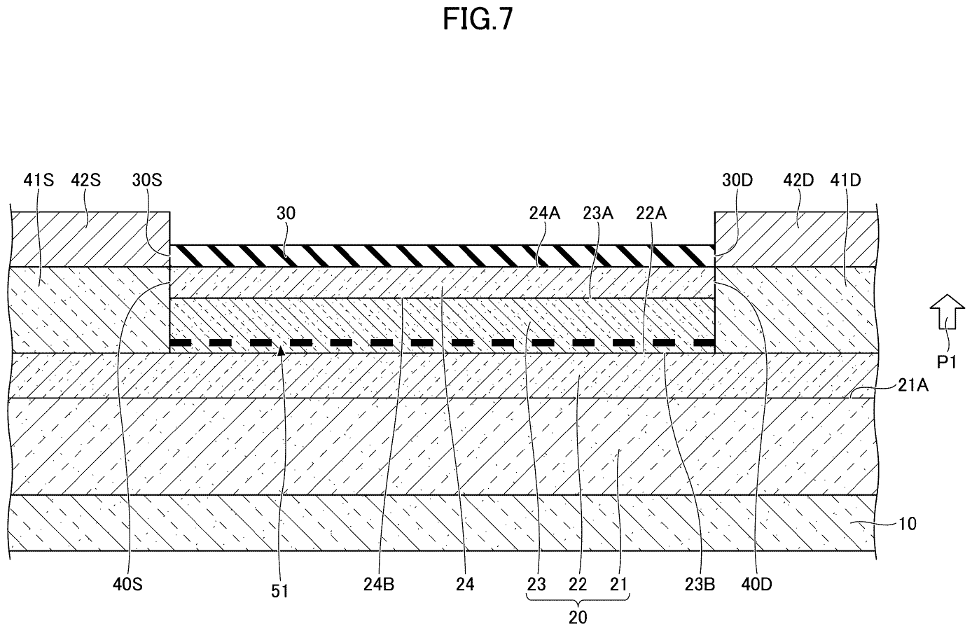

Next, as illustrated in FIG. 7, the source electrode 42S is formed over the regrowth layer 41S, and the drain electrode 42D is formed over the regrowth layer 41D. In the formation of the source electrode 42S and the drain electrode 42D, first, a metal layer (not shown) forming the source electrode 42S and the drain electrode 42D is formed. In the formation of the metal layer, for example, a film is formed using a mask for growth (not shown) including an opening formed in a region where the metal layer is to be formed, and then the mask for growth is removed along with the metal layer (not shown) formed on the mask for growth. That is, lift-off is performed.

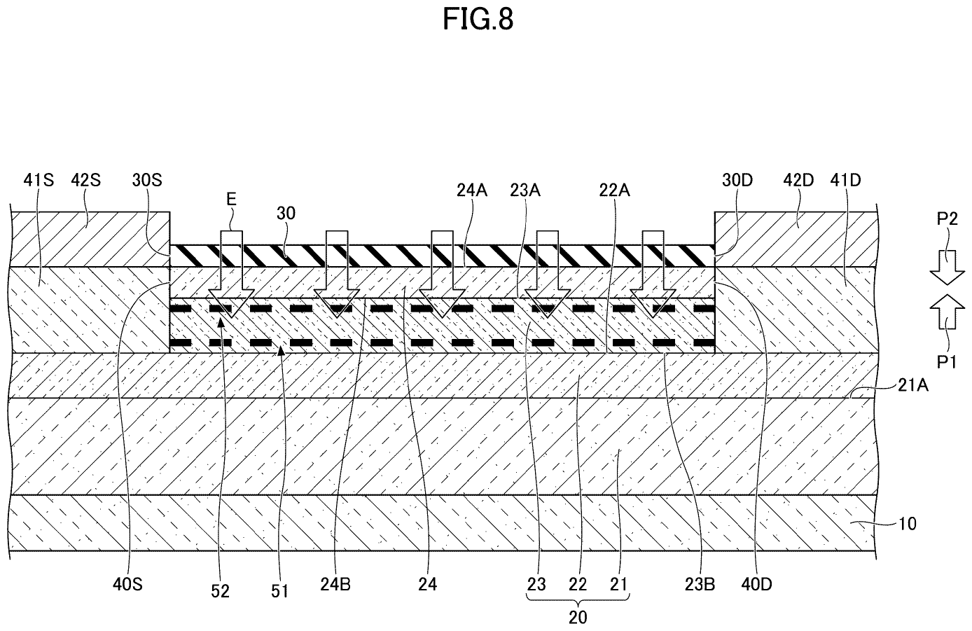

Next, as illustrated in FIG. 8, by applying, to the ferroelectric layer 24, an electric field E equal to or greater than the coercive electric field of the ferroelectric layer 24, the ferroelectric layer 24 is caused to have the polarization P2 directed opposite to the polarization P1. As a result, the two-dimensional electron gas 52 is generated near the top surface 23A of the channel layer 23. The electric field E can be applied, for example, by irradiation with corona charges or by application of a voltage to an electrode (not shown) separately provided on the top surface 24A of the ferroelectric layer 24, while providing a ground potential to the source electrode 42S. When controlling the polarization P2, the ferroelectric layer 24 may be heated to a temperature that is about 500 degrees Celsius (° C.) or less.

Next, the opening 30G for the gate is formed in the insulating film 30 (see FIG. 1). The opening 30G can be formed, for example, through RIE using a mask (not shown). Next, the gate electrode 43 to contact the ferroelectric layer 24 through the opening 30G is formed over the insulating film 30 (see FIG. 1). In the formation of the gate electrode 43, for example, a metal layer is formed using a mask for growth (not shown) including an opening formed in a region where the gate electrode 43 is to be formed, and then the mask for growth is removed along with the metal layer (not shown) formed on the mask for growth. That is, lift-off is performed.

In this manner, the nitride semiconductor transistor 1 can be produced.

No particular limitation is imposed on the method and timing for controlling the polarization of the ferroelectric layer 24.

The nitride semiconductor transistor 1 may include an insulating layer between the ferroelectric layer 24 and the gate electrode 43, or may include an insulating layer between the ferroelectric layer 24 and the channel layer 23. The electron affinity of these insulating layers is lower than the electron affinity of the ferroelectric layer 24.

Although the embodiments have been described above in detail, the present disclosure is not limited to the specific embodiments. Various modifications and alterations are possible within the scope of claims recited.

According to the present disclosure, it is possible to enhance distortion characteristics.

What is claimed is:

1. A nitride semiconductor transistor, comprising:
a barrier layer including a first top surface having nitrogen polarity;
a channel layer located over the first top surface and including a second top surface having the nitrogen polarity, the channel layer having a first polarization in a first direction; and
a ferroelectric layer located over the second top surface and having a second polarization in a second direction opposite to the first direction.

2. The nitride semiconductor transistor according to claim 1, wherein
the channel layer includes a bottom surface opposite to the second top surface, and
the channel layer includes
a first two-dimensional electron gas positioned closer to the bottom surface than to the second top surface, and
a second two-dimensional electron gas positioned closer to the second top surface than to the bottom surface.

3. The nitride semiconductor transistor according to claim 1, wherein
the ferroelectric layer is a nitride layer containing aluminum, and at least one selected from the group consisting of scandium, boron, and yttrium.

4. The nitride semiconductor transistor according to claim 3, wherein
the ferroelectric layer is an aluminum scandium nitride layer, and
in the aluminum scandium nitride layer, a ratio of a number of scandium atoms to a total number of aluminum atoms and the scandium atoms is 40% or less.

5. The nitride semiconductor transistor according to claim 3, wherein
the ferroelectric layer is an aluminum yttrium nitride layer, and
in the aluminum yttrium nitride layer, a ratio of a number of yttrium atoms to a total number of aluminum atoms and the yttrium atoms is 80% or less.

6. The nitride semiconductor transistor according to claim 1, wherein
the ferroelectric layer is a hafnium oxide layer containing at least one selected from the group consisting of zirconium, yttrium, lanthanum, and silicon.

7. The nitride semiconductor transistor according to claim 6, wherein
the ferroelectric layer is a hafnium zirconium oxide layer, and
in the hafnium zirconium oxide layer, a ratio of a number of zirconium atoms to a total number of hafnium atoms and the zirconium atoms is 45% or more and 55% or less.

8. The nitride semiconductor transistor according to claim 6, wherein
the ferroelectric layer is a hafnium yttrium oxide layer, and
in the hafnium yttrium oxide layer, a ratio of a number of yttrium atoms to a total number of hafnium atoms and the yttrium atoms is 3% or more and 7% or less.

9. The nitride semiconductor transistor according to claim 6, wherein
the ferroelectric layer is a hafnium lanthanum oxide layer, and
in the hafnium lanthanum oxide layer, a ratio of a number of lanthanum atoms to a total number of hafnium atoms and the lanthanum atoms is 1% or more and 7% or less.

10. The nitride semiconductor transistor according to claim 6, wherein
the ferroelectric layer is a hafnium silicon oxide layer, and
in the hafnium silicon oxide layer, a ratio of a number of silicon atoms to a total number of hafnium atoms and the silicon atoms is 2% or more and 9% or less.

11. The nitride semiconductor transistor according to claim 1, wherein
the ferroelectric layer is an oxide layer containing at least one selected from the group consisting of barium, bismuth, lead, and titanium, and having a perovskite-type crystal structure.
